(19) United States
(12) Patent Application Publication
(10) Pub. No.: US 2026/0072171 A1
(43) Pub. Date: Mar. 12, 2026

(54) TIME-OF-FLIGHT SENSOR AND METHODS FOR MAKING

(71) Applicant: Taiwan Semiconductor Manufacturing Company, Ltd., Hsinchu (TW)

(72) Inventors: Tzu Jung Tien, Hsinchu (TW); Cheung Cheng, Hsinchu (TW)

(21) Appl. No.: 18/882,250

(22) Filed: Sep. 11, 2024

(51) Int. Cl. G01S 17/894; G01S 7/481

(52) U.S. Cl. CPC G01S 17/894; G01S 7/4814; G01S 7/4816

(57) ABSTRACT

Time-of-Flight (ToF) sensors and methods for making are disclosed. A light-emitting diode is adjacent to an image sensor, and they are separated by an opaque wall to block direct light paths. The ToF sensor is smaller in both area and height, and has reduced power consumption.

### BACKGROUND

Time-of-flight (ToF) measurement of light generated by a light source can be used to measure the distance between the light source and a target. Such measurement is based on detection of light from the light source which is reflected by the target back to a detector.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a first embodiment of a Time-of-Flight (ToF) sensor that includes a light-emitting diode (LED) and an image sensor, in accordance with some embodiments of the present disclosure. This sensor is a back-side-illuminated (BSI) sensor.

FIG. 1B is a plan view of the ToF sensor of FIG. 1A.

FIG. 1C is a cross-sectional view of a second embodiment of the ToF sensor.

FIG. 1D is a cross-sectional view of a third embodiment of the ToF sensor.

FIG. 2A is a cross-sectional view of another embodiment of a ToF sensor, in accordance with some embodiments of the present disclosure. This sensor is a front-side-illuminated (FSI) sensor.

FIG. 2B is a plan view of the ToF sensor of FIG. 2A.

FIG. 3A and FIG. 3B together form a flow chart illustrating a first method for making a ToF sensor, in accordance with some embodiments. In particular, the method is used for making a BSI ToF sensor, such as that illustrated in FIG. 1A.

FIG. 4 is a side cross-sectional view of the bottom die substrate after n-wells and p-wells are formed on a first side of the substrate.

FIG. 5 is a side cross-sectional view of the bottom die substrate after transistors are formed in the n-wells and p-wells.

FIG. 6 is a side cross-sectional view of the bottom die substrate after an interconnect layer including metal routing and contact vias is formed.

FIG. 7 is a side cross-sectional view of the bottom die substrate after etching the interconnect layer in an LED area.

FIG. 8 is a side cross-sectional view of the bottom die substrate after LED material is applied to form the LED.

FIG. 9 is a side cross-sectional view of the top die substrate after forming a first deep well of a first dopant type and a channel of a first dopant type in the substrate.

FIG. 10 is a side cross-sectional view of the top die substrate after forming a second deep well of the first dopant type and a first well of a second dopant type around the channel at a different depth.

FIG. 11 is a side cross-sectional view of the top die substrate after forming an electrode of the first dopant type contacting the channel and an electrode of the second dopant type within the first well of the second dopant type.

FIG. 12 is a side cross-sectional view of the top die substrate after an interconnect layer including metal routing and contact vias is formed.

FIG. 13 is a side cross-sectional view of the top die substrate after forming a deep trench.

FIG. 14 is a side cross-sectional view of the top die substrate after filling the deep trench to form an opaque wall.

FIG. 15 is a side cross-sectional view of the top die substrate after a carrier wafer has been applied and the backside of the substrate has been ground to expose the first deep well of the first dopant type.

FIG. 16 is a side cross-sectional view of the top die substrate after being flipped over.

FIG. 17 is a flow chart illustrating a second method for making a ToF sensor, in accordance with some embodiments. In particular, the method is used for making an FSI ToF sensor, such as that illustrated in FIG. 2A.

FIG. 18 is a side cross-sectional view of the substrate after forming a first deep well of a first dopant type, a channel of a first dopant type in the substrate, and a second deep well of the first dopant type around the channel at a different depth from the first deep well.

FIG. 19 is a side cross-sectional view of the substrate after forming a first well of a second dopant type around the channel. One or more wells, gate dielectric layers, and gate electrodes are also formed in an LED area.

FIG. 20 is a side cross-sectional view of the substrate after source/drain electrodes are formed in the channel, the first well of the second dopant type, and the one or more wells in the LED area.

FIG. 21 is a side cross-sectional view of the substrate after a protective layer is formed over the image sensor. The source/drain electrodes of the image sensor remain exposed.

FIG. 22 is a side cross-sectional view of the substrate after a dielectric layer and electrical interconnects are formed. At least one contact extends from the peripheral source/drain electrode of the image sensor.

FIG. 23 is a side cross-sectional view of the substrate after forming a deep trench in the dielectric layer between the LED area and the image sensor.

FIG. 24 is a side cross-sectional view of the substrate after filling the deep trench to form an opaque wall.

FIG. 25 is a side cross-sectional view of the substrate after etching the dielectric layer in an LED area.

FIG. 26 is a flow chart illustrating a method for using a ToF sensor to measure a distance, in accordance with some embodiments.

FIG. 27 is a schematic diagram of a device containing a ToF sensor and measuring the distance to a target, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The terms “annular” or “annulus” refer to the planar shape formed by the area between two concentric shapes whose edges are parallel to each other. These terms can refer, for example to the ring shape bounded by two concentric circles, or to the shape contained between two squares with a common center whose sides are parallel to each other.

The term “die”, as used in the present disclosure, refers to the combination of one or more integrated circuits (also referred to as chip or microchip) and an interconnect layer that permits the integrated circuit(s) to communicate with one or more other dies. Examples of an interconnect layer may include a redistribution layer (RDL) or an interposer having bond pads or C4 bumps or pillars. A die may have an interconnect layer on only one side, or on both sides.

The present disclosure relates to various sensors/systems or modules for measuring the distance between two objects, and methods and making and using such sensors. The systems/modules operate based on time-of-flight (ToF), and are formed from two semiconductor dies. The resulting sensors are much smaller than conventional systems, with reduced surface area and reduced height/thickness. The sensors also have reduced power consumption, and do not need a conventional large housing to separate the light source from the image sensor.

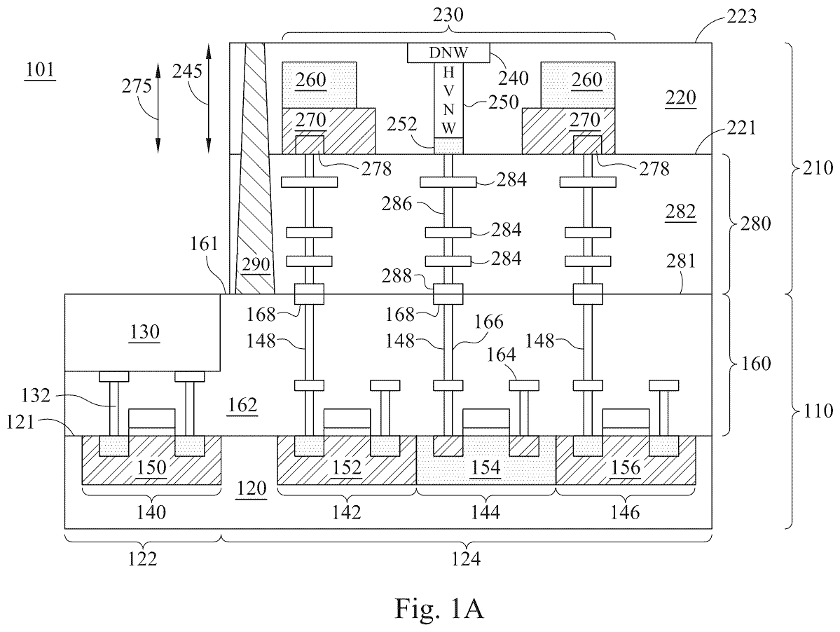

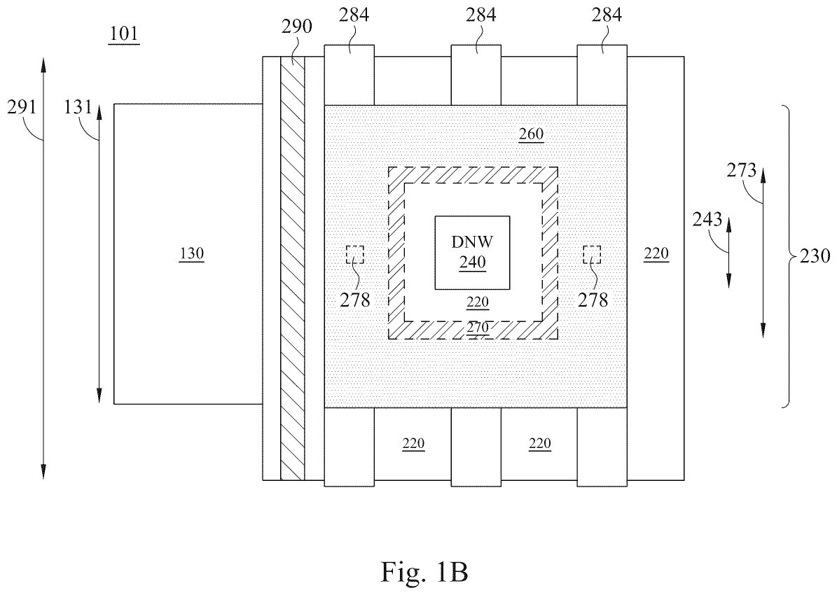

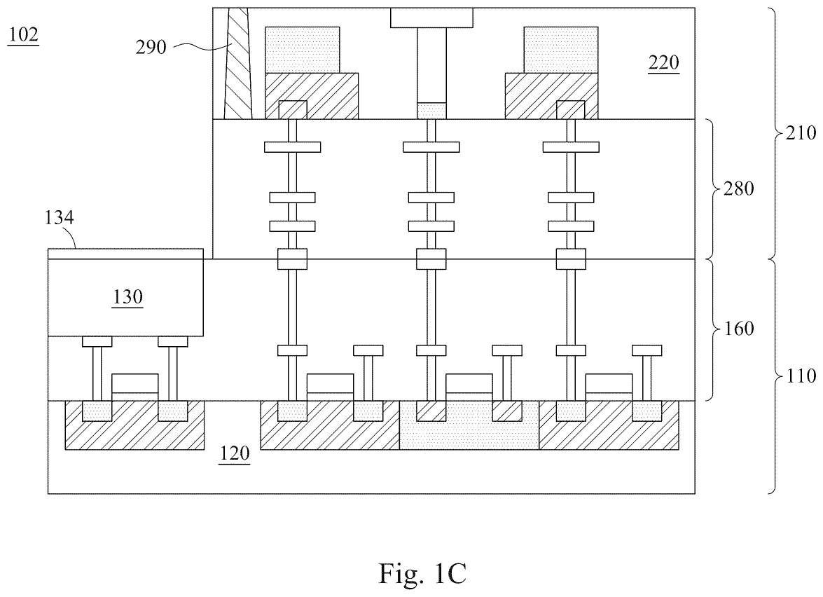

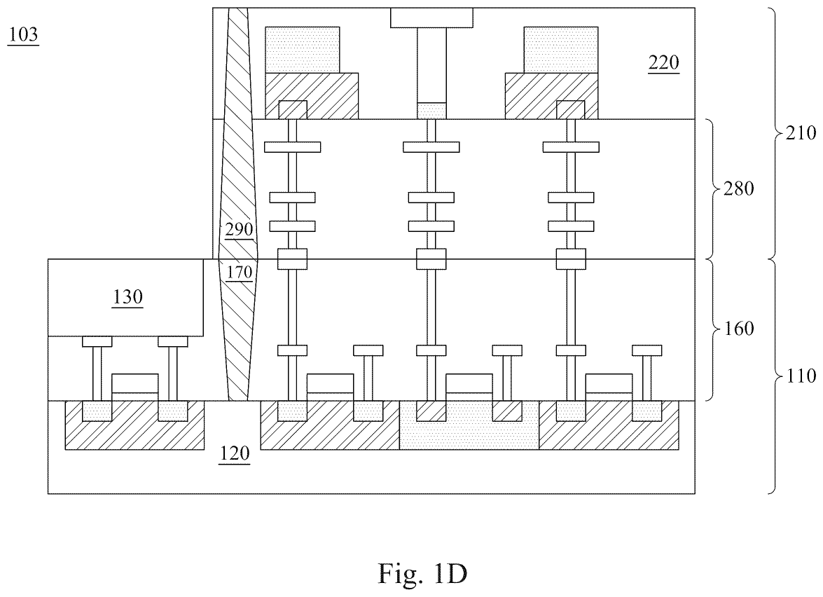

FIG. 1A is a side cross-sectional view showing a first example of a ToF sensor 101 formed by hybrid bonding of two semiconductor dies, in accordance with some embodiments of the present disclosure, and illustrating some features. FIG. 1B is a plan view of the sensor along line B-B of FIG. 1A. This particular system is a back-side-illuminated (BSI) sensor.

The sensor 101 includes two semiconductor dies, a first die 110 (or bottom die) and a second die package 210 (or top die). Referring first to FIG. 1A, the bottom die 110 includes a substrate 120 which has an LED area 122 and a logic area 124. An interconnect layer 160 is present over a first side or top surface 121 of the substrate. One or more active devices, such as transistor 140, are present in the substrate in the LED area. The transistors 140 are electrically connected to a light-emitting diode (LED) 130 through electrical interconnects 132. The logic area 124 also includes one or more active devices in the substrate, such as transistors. Here, three transistors 142, 144, 146 are illustrated. Electrical interconnects 148 extend from the active devices in the logic area to the top surface 161 of the interconnect layer 160.

Each transistor is formed within a well of a first dopant type or a well of a second dopant type. The first dopant type and the second dopant type are different from each other in their charge, i.e. one is positively charged and one is negatively charged. If the first dopant type is an n-type dopant, then the second dopant type is a p-type dopant, or vice versa. As illustrated here, the first dopant type is n-type, and the second dopant type is p-type.

As illustrated here, transistors 140, 142, 146 are located within wells of a first dopant type 150, 152, 156 and a transistor 144 is located within a well of the second dopant type 154. In the logic area, it is noted that the transistors 142, 144, 146 alternate, with second dopant type well 154 being located between two first dopant type wells 152, 156. They may change depending on whether an NMOS or a PMOS is desired. It is noted that only one transistor 140 is shown in the LED area 122. The type of wells in the LED area 122 and the logic area 124 may vary as desired, and there is no required relationship between their type. For example, transistor 140 in the LED area could be located within either a p-well or an n-well with no change required in the wells 152, 154, 156 in the logic area.

Continuing, the interconnect layer 160 is formed from a dielectric material 162, and includes electrical interconnects in the LED area and the logic area, including horizontally-oriented metal routing 164 and vertically-oriented contact vias 166 which are electrically connected to the source/drain electrodes of the transistors 142, 144, 146. Bond pads 168 are electrically connected to the metal routing and contact vias, and are present at the first or top surface 161 of the interconnect layer 160.

The top die 210 includes a substrate 220, and an image sensor 230 is formed in the substrate. The substrate has a first side or surface 221 and an opposite spaced-apart second side or surface 223 which define the thickness of the substrate.

The image sensor is an avalanche photodiode, such as a single photon avalanche diode (SPAD). An avalanche process can be triggered by very low intensities, as low as a single photon. When a reverse-biased p-n junction receives additional energy from incident light, the energy causes charge carriers to separate and at high enough energies, these charge carriers can cause additional charge carriers to separate and create an avalanche effect, causing a current to flow through the diode.

Here, the image sensor (SPAD) includes a first deep well of a first dopant type 240 which is located at a first depth 245 measured relative to the first side 221 of the substrate, shown here along the second side 223 of the substrate 220. A channel of the first dopant type 250 contacts the first deep well of the first dopant type 240, and extends towards the first side 221. An electrode of the first dopant type 252 contacts the channel of the first dopant type 250, and is present along the first side 221 of the substrate.

Referring to both FIG. 1A and FIG. 1B, a second deep well of the first dopant type 260 is located around the first deep well of the first dopant type 240. The second deep well of the first dopant type 260 is located at a second depth 275 which is different from the first depth 245. The second deep well of the first dopant type 260 is also located around the channel of the first dopant type 250. A first well of a second dopant type 270 is also located around the first deep well of the first dopant type 240. The first well of the second dopant type 270 is also located around the channel of the first dopant type 250. The first well of the second dopant type 270 contacts the second deep well of the first dopant type 260, and is also present upon the first side 221 of the substrate. One or more electrodes of a second dopant type 278 are present within the first well of the second dopant type 270. Here, two such electrodes are illustrated.

As best seen in FIG. 1B, the first deep well of the first dopant type 240 is surrounded by both the second deep well of the first dopant type 260 and the first well of the second dopant type 270. The second deep well of the first dopant type 260 and the first well of the second dopant type 270 each form an annulus around the first deep well of the first dopant type 240. The first well of the second dopant type 270 has an inner width 273, and the first deep well of the first dopant type 240 has a width 243 that is less than the inner width 273. Metal routing 284 is shown extending beyond the dimensions of the image sensor 230. The electrodes 278 are also indicated in dashed line.

Continuing, an interconnect layer 280 is present over the first side 221 of the substrate. The interconnect layer 280 includes a dielectric material 282 with horizontally-oriented metal routing 284 and vertically-oriented contact vias 286 which are electrically connected to the electrodes 252, 278. Bond pads 288 are electrically connected to the metal routing and contact vias, and are present at the first side 281 of the interconnect layer 280.

In some embodiments, an opaque wall 290 is present on at least one side of the top die 210. The opaque wall 290 is located outside of the first well of the second dopant type 270. As illustrated in FIG. 1A, the opaque wall extends through both the substrate 220 and the interconnect layer 280. As illustrated in FIG. 1B, in some embodiments, the opaque wall 290 may have a length 291 which is greater than or equal to a length 131 of the LED 130. The opaque wall is intended to block any direct light paths from the LED 130 to the image sensor 230, such that only light which has reflected from a target is captured by the image sensor 230. However, the opaque wall is optional and in some contemplated embodiments, the opaque wall is not present.

Continuing, the first side 281 of the interconnect layer of the top die 210 is bonded to the first or top surface 161 of the interconnect layer of the bottom die 110. The top die 210 is located over the logic area 124 of the bottom die. The electrode of the first dopant type 252 of the top die is electrically connected to an active device 144 located within a well of the first dopant type 154. Similarly, the electrode(s) of the second dopant type 278 of the top die are electrically connected to an active device 142, 146 located within a well of the second dopant type 152, 156. It is noted that the metal routing 164, 284 permits the image sensor 230 to be connected to as many active devices as desired, and the image sensor 230 is not necessarily connected to only the three transistors 142, 144, 146 shown in FIG. 1A.

FIG. 1C is a cross-sectional view of a second embodiment 102 of the ToF sensor. Here, the opaque wall 290 is located within only the substrate 220 of the top die, and does not extend through the interconnect layer 280. In addition, a color filter 134 is present upon the LED 130. This may be desirable in some applications.

FIG. 1D is a cross-sectional view of a third embodiment 103 of the ToF sensor. Here, an opaque wall 170 is also present extending through the interconnect layer 160 of the bottom die 110. The opaque wall 290 of the top die extends through both the substrate 220 and the interconnect layer 280. The two opaque walls 170, 290 are aligned with each other to form a single wall extending throughout the sensor/system.

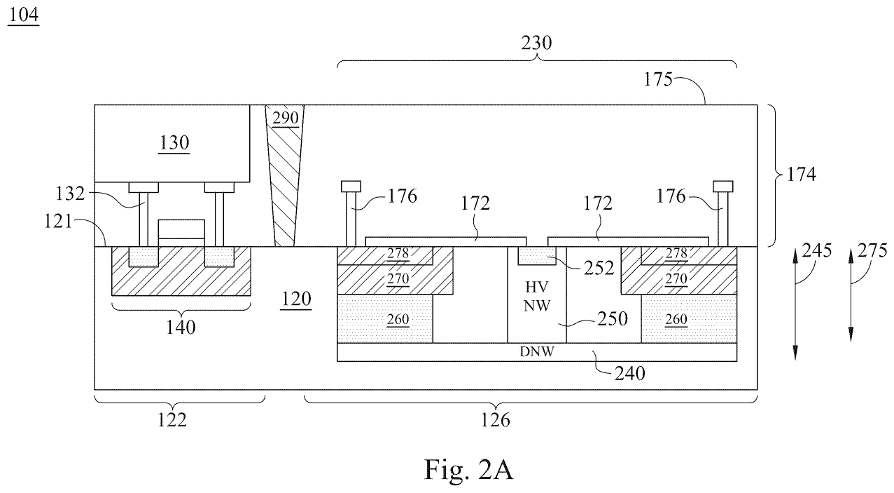

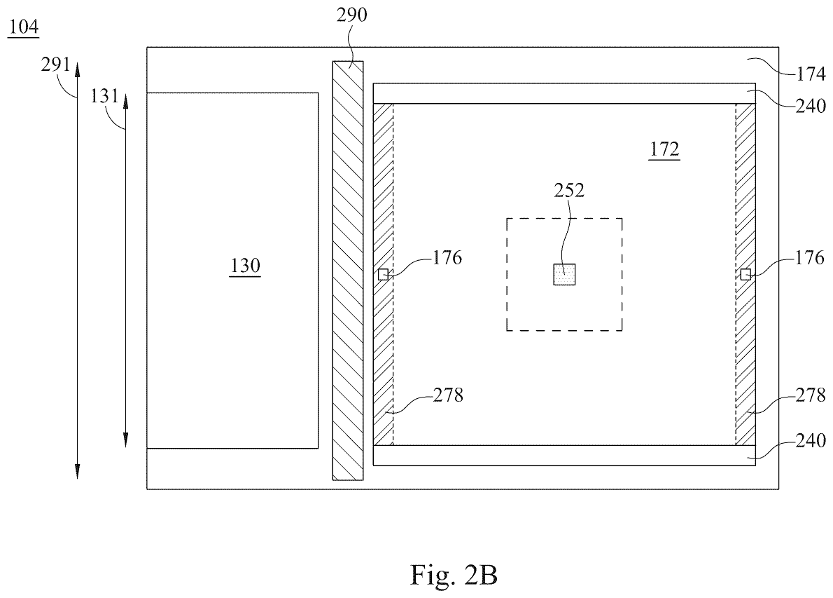

FIG. 2A is a cross-sectional view of another embodiment of a ToF sensor system 104, in accordance with some embodiments of the present disclosure. FIG. 2B is a plan view. This particular system is a front-side-illuminated (FSI) sensor.

The substrate 120 has an LED area 122 and an image sensor area 126. Again, one or more active devices, such as transistor 140, are present in the substrate in the LED area. The transistor(s) 140 are electrically connected to a light-emitting diode (LED) 130 through electrical interconnects 132.

Continuing, the image sensor 230 of FIG. 2A has a similar structure to that described and illustrated in FIG. 1A. Again, the image sensor includes a first deep well of a first dopant type 240, which is located at a first depth 245. A channel of the first dopant type 250 contacts the first deep well of the first dopant type 240 and, as illustrated here, extends to the first or top side 121 of the substrate. An electrode of the first dopant type 252 is present within the channel of the first dopant type 250, and contacts the first side 121 of the substrate. A second deep well of the first dopant type 260 is located around the first deep well of the first dopant type 240 at a second depth 275 which is different from the first depth 245. The second deep well of the first dopant type 260 is also located around the channel of the first dopant type 250. A first well of a second dopant type 270 is also located around the first deep well of the first dopant type 240, and contacts the second deep well of the first dopant type 260, and is also present upon the first side 121 of the substrate. One or more electrodes of a second dopant type 278 are present within the first well of the second dopant type 270. Here, two such electrodes are illustrated. The electrode of the first dopant type 252 may also be referred to as a central source/drain electrode, and each electrode of the second dopant type 278 may also be referred to as a peripheral source/drain electrode.

A protective layer 172 is present upon the substrate over the image sensor 230. The electrodes 252, 278 are at least partially exposed, or put another way the protective layer does not entirely cover the electrodes. A dielectric layer 174 is present upon the first side 121 of the substrate. The dielectric layer extends over both the LED area 122 and the image sensor area 126. At least one contact 176 extends from the peripheral source/drain electrode 278 into the dielectric layer. The contact(s) 176 will collect electrons during operation of the SPAD.

An opaque wall 290 is present upon the substrate, extending from the top surface 175 through the dielectric layer 174 to the first side 121 of the substrate. The opaque wall 290 is located between the LED 130 and the image sensor 230, or between the LED area 122 and the image sensor area 126. Again, as illustrated in FIG. 2B, in some embodiments, the opaque wall 290 may have a length 291 which is greater than or equal to a length 131 of the LED 130.

In FIG. 2B, the long dash line indicates the perimeter of the first well of the second dopant type 270 below the protective layer 172. The short dashed line indicates the perimeter of the first deep well of the first dopant type 240. The central electrode 252 and the peripheral electrodes 278 are also labeled, along with the contacts 176.

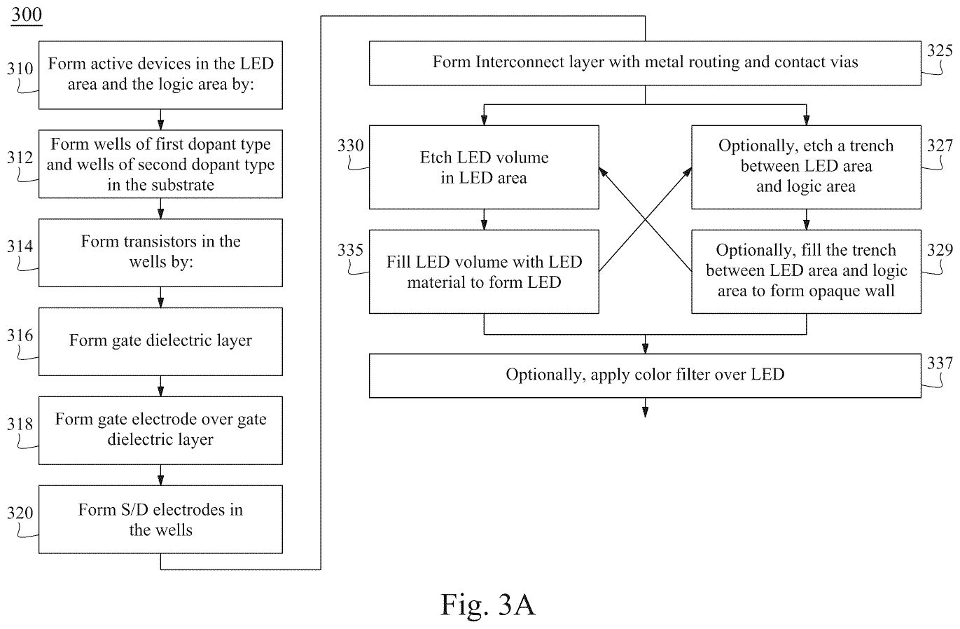

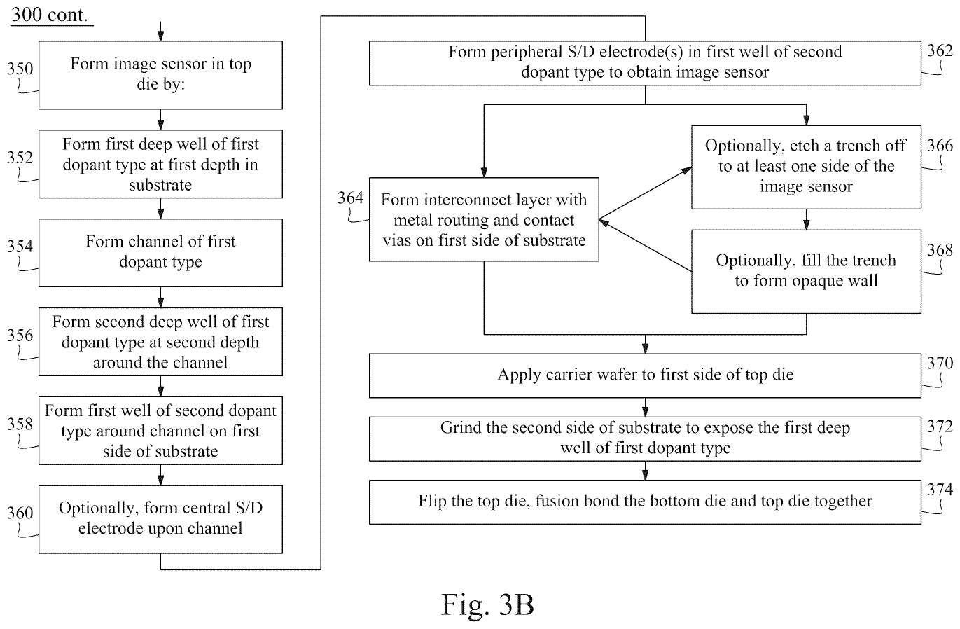

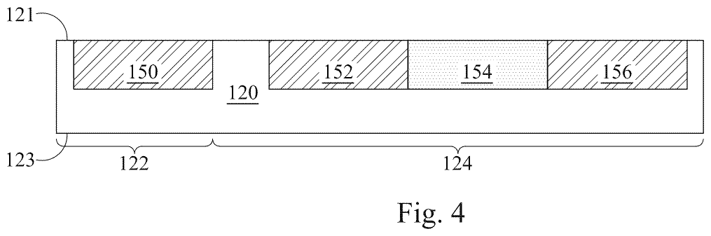

FIG. 3A and FIG. 3B together form a flow chart illustrating a method 300 for making a Time-of-Flight (ToF) sensor, more particularly a BSI ToF sensor. Some steps of the method are also illustrated in FIGS. 4-16. The method steps are discussed below in terms of forming a single sensor, but should also be broadly construed as applying to the concurrent formation of multiple sensor components. Additional steps may be performed between the various steps described herein, and some are omitted merely for clarity. Not all method steps may be needed to obtain the structures disclosed herein. Additionally, some of the method steps can be performed simultaneously, or in a different order than as shown or described here. The bottom die and the top die may be separately manufactured, and then combined. The construction of the bottom die is described first.

Initially, referring to FIG. 4, the bottom die is formed upon and within a substrate 120. The substrate is made of a semiconducting material, and is provided in the form of a wafer. Such semiconducting materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

The substrate 120 of the bottom die has a first side 121 and an opposite second side 123. The substrate 120 of the bottom die includes an LED area 122 and a logic area 124. Next, as indicated in step 310 of FIG. 3A, active devices are formed in the LED area 122 and the logic area 124. As indicated in step 312 of FIG. 3A and as illustrated in FIG. 4, one or more wells of the first dopant type and one or more wells of the second dopant type are formed in the substrate. This is done on the first side 121 of the substrate. Here, four wells are shown, three 150, 152, 156 being illustrated as n-wells and one 154 being illustrated as a p-well. This may be done, for example, using separate ion implantation steps.

Implantation of various ions into a silicon crystal lattice modifies the conductivity of the lattice in the implanted location, permitting the manufacture of the various parts of the optical modulator. An ion implanter generally includes an ion source, a beam line, and a process chamber. The ion source produces desired ions which act as dopants to change various properties in desired locations of the base layer. For example, positive and negative electrical contacts are formed using dopants that have a different polarity from the substrate. Common p-type dopants may include boron, gallium, or indium. Common n-type dopants may include phosphorus or arsenic. The resulting ion beam enters the beam line, which organizes the ions into a beam having high purity in terms of ion mass, energy, and species. The ion beam is then used to irradiate the wafer substrate in the process chamber.

With respect to the wells 150, 152, 154, 156 the implantation depths for the two dopant types are designed to be the same. However, their energy levels will depend on their size and atomic weight, and thus may vary.

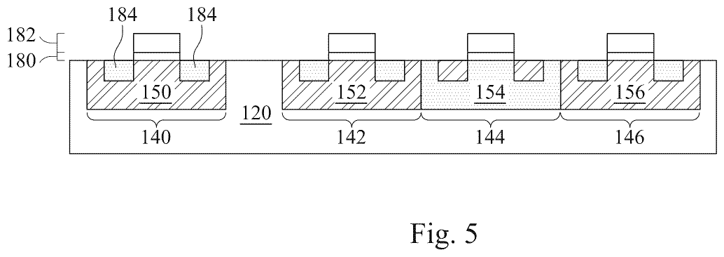

Next, as indicated in step 314 of FIG. 3A and with reference to FIG. 5, transistors 140, 142, 144, 146 are formed in the wells. In step 316, a dielectric layer is formed upon the substrate and patterned to form the gate dielectric layer 180 of each transistor. In step 318, a gate material is deposited and patterned to form the gate electrode 182 of each transistor. The gate electrode 182 is located upon the gate dielectric layer 180 of each transistor. The gate material may be, for example, polysilicon or an electrically conductive metal. These deposition steps may be done by chemical vapor deposition (CVD), physical vapor deposition (PVD), atomic layer deposition (ALD), or other suitable process. Then, in step 320 of FIG. 3A, source/drain (S/D) electrodes 184 are formed within the wells 150, 152, 154, 156. It is noted that p-type electrodes are formed in each n-well, and n-type electrodes are formed in each p-well. If desired, the S/D electrodes can be formed before the gate dielectric layer and the gate electrode are formed. The resulting structure is shown in FIG. 5. It is particularly noted that more than one transistor can be formed in the LED area 122. In some embodiments, an LED may be driven by 4 to 7 transistors.

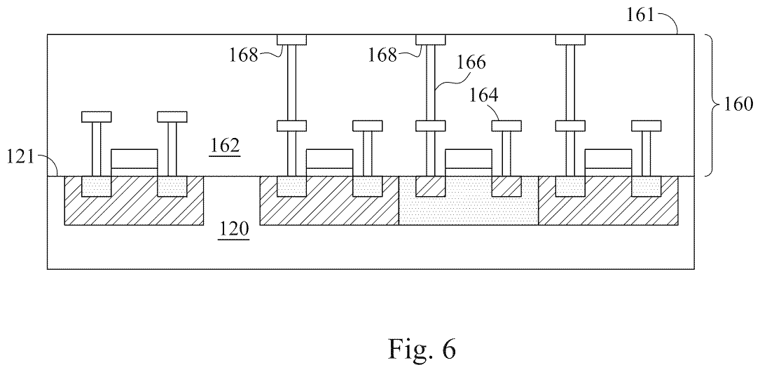

Next, as indicated in step 325 of FIG. 3A and as illustrated in FIG. 6, an interconnect layer 160 is formed. The interconnect layer 160 includes a dielectric material 162 and electrically conductive components within the dielectric material. The interconnect layer may also be considered a redistribution layer (RDL). As illustrated here, the electrically conductive components include metal routing 164 and contact vias 166. However, generally speaking, any electrical circuit with any desired structure and made up of any desired components is contemplated. The interconnect layer 160 may be formed in several different steps that build several smaller layers that together form the interconnect layer. For example, a first dielectric layer may be deposited, then etched to form openings that are filled with an electrically conductive material to obtain the metal routing or contact vias. Non-limiting examples of suitable electrically conductive materials can include metals like copper, aluminum, gold, tungsten, iron, ruthenium, iridium, and alloys thereof. This may be repeated to locate the electrically conductive components in desired locations. Bond pads 168 are also formed at a top surface 161 of the interconnect layer.

If the embodiment of FIG. 1D is desired, then as indicated in step 327 of FIG. 3A, a trench may be formed in the interconnect layer between the LED area 122 and the logic area 124. This is usually performed by patterning and etching. The trench extends from the top surface 161 of the interconnect layer to the first side 121 of the substrate. Then, in step 329 of FIG. 3A, the trench is filled with an opaque material to form the opaque wall 170. The opaque material does not permit light to pass through the opaque wall. For example, the opaque material may be a metal such as aluminum or copper.

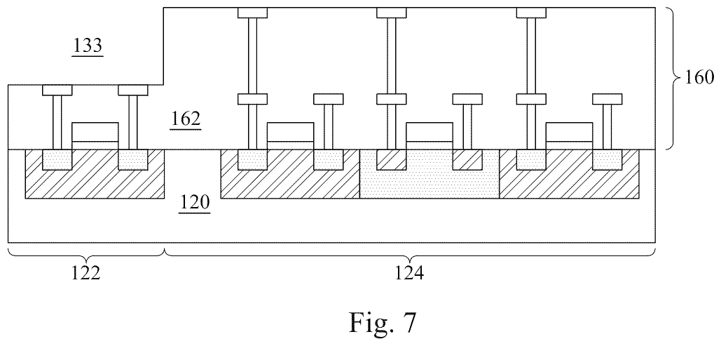

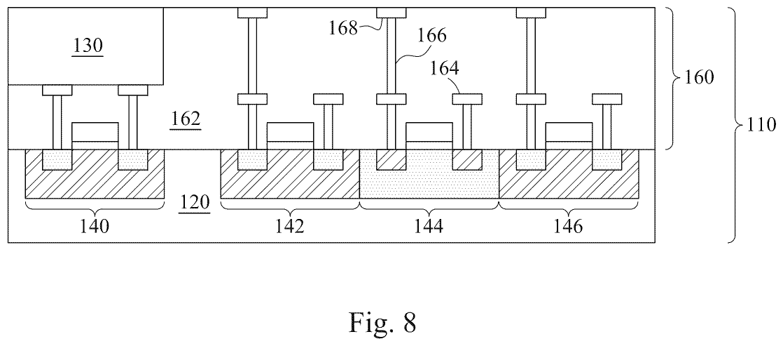

Continuing, as indicated in step 330 of FIG. 3A and as illustrated in FIG. 7, the interconnect layer 160 is etched in the LED area 122 to form an LED volume 133. Then, as indicated in step 335 of FIG. 3A and as illustrated in FIG. 8, the LED volume is filled with an LED material to form the LED 130. The LED material may also be an OLED material, in some embodiments. The resulting structure corresponds to the bottom die 110 of FIG. 1A. If a color filter 134 is desired as illustrated in FIG. 1C, then in optional step 337 of FIG. 3A, a color filter is applied to the LED 130. It is noted that although the opaque wall 170 is described as being formed before the LED 130 is formed, the opaque wall can also be formed afterwards.

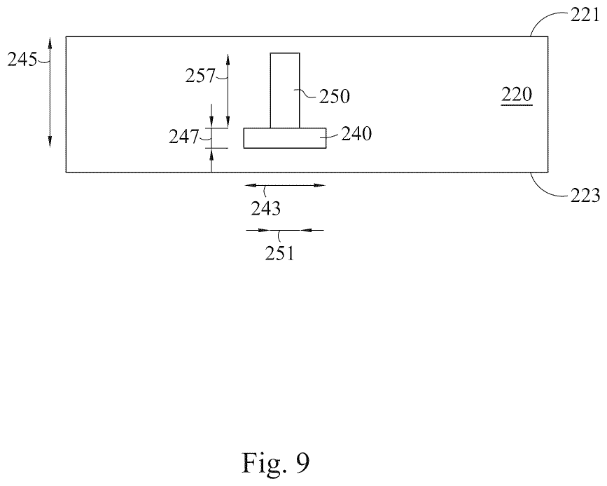

The formation of the image sensor (SPAD) in the top die is now discussed. Referring to FIG. 9, the top die is also formed upon and within a substrate 220. The substrate may be as previously described. The substrate 220 of the top die also has a first side 221 and an opposite second side 223. Next, as indicated in step 350 of FIG. 3B, an image sensor is formed in the substrate 220. The image sensor may be formed in multiple steps.

In step 352 of FIG. 3B, a first deep well of a first dopant type 240 is formed in the substrate at a first depth 245 relative to the first surface 221. The first deep well of the first dopant type may be considered as being proximate the second side 223 of the substrate. Then, in step 354, a channel of the first dopant type 250 is formed in the substrate. The channel contacts the first deep well of the first dopant type 240 at one end, and extends towards the first side 221 of the substrate. The first deep well of the first dopant type and the channel may be formed in separate ion implantation steps. It is particularly noted that the channel does not need to be formed in one ion implantation step, but can be formed in multiple implantation steps (e.g. changing the implantation energy to spread the ions across the depth of the channel).

As illustrated here, the width 243 of the first deep well of the first dopant type is greater than the width 251 of the channel. In addition, the height/thickness 247 of the first deep well of the first dopant type is less than the height/thickness 257 of the channel.

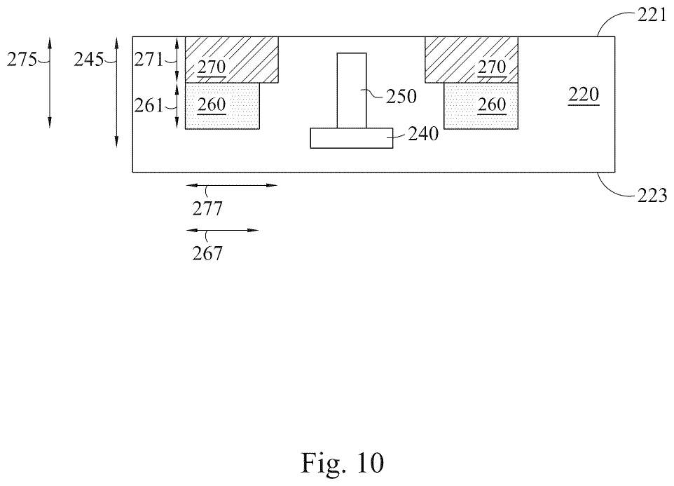

Continuing, in step 356 of FIG. 3B and as illustrated in FIG. 10, the second deep well of the first dopant type 260 is formed around the first deep well of the first dopant type 240 at a second depth 275 which is different from the first depth 245. The second deep well of the first dopant type 260 can also be described as being formed around the channel 250. Then, in step 358, the first well of the second dopant type 270 is formed upon the first side 221 of the substrate. Put another way, the first well of the second dopant type 270 is exposed upon the first side 221 of the substrate. The first well of the second dopant type 270 also contacts the second deep well of the first dopant type 260. The first well of the second dopant type 270 is also located around the first deep well of the first dopant type 240, or the channel 250 (when seen from a plan view). The second deep well of the first dopant type 260 and the first well of the second dopant type 270 can also be formed using ion implantation.

The thickness 261 of the second deep well of the first dopant type 260 and the thickness 271 of the first well of the second dopant type 270 are, in particular embodiments, about equal to each other. As previously mentioned, the second deep well of the first dopant type 260 and the first well of the second dopant type 270 each have an annular shape. Their widths 267, 277 may also be about equal to each other in particular embodiments. Other values and ranges for these properties are also within the scope of the present disclosure.

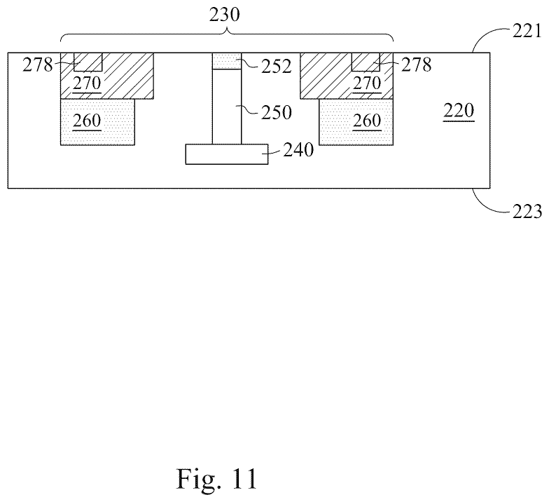

As illustrated, the channel 250 does not extend to the first side 221 of the substrate. Continuing then, as indicated in optional step 360 of FIG. 3B and as illustrated in FIG. 11, a source/drain electrode of the first dopant type 252 is formed. Ion implantation may be used. This source/drain electrode may also be considered a central source/drain electrode, and contacts the channel 250. However in some embodiments, it is contemplated that the channel 250 does extend to the first side 221 of the substrate, in which case the channel can act as the source/drain electrode. Then, in step 362 of FIG. 3B, one or more source/drain electrodes of the second dopant type 278 are formed within the first well of the second dopant type 270. As a result, the image sensor 230 is formed.

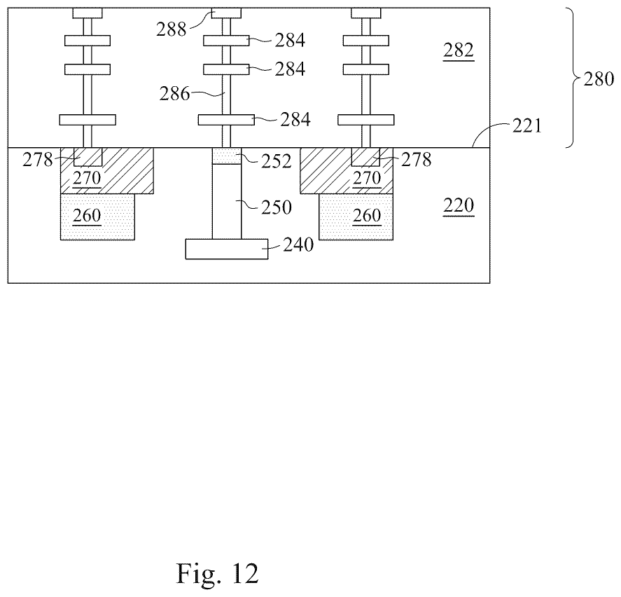

Next, in step 364 of FIG. 3B and as illustrated in FIG. 12, an interconnect layer 280 is formed upon the first side 221 of the substrate. The interconnect layer 280 includes a dielectric material 282 and electrically conductive components within the dielectric material, such as metal routing 284, contact vias 286, and bond pads 288. The interconnect layer may be formed by repeated steps of deposition and etching to obtain the desired structure.

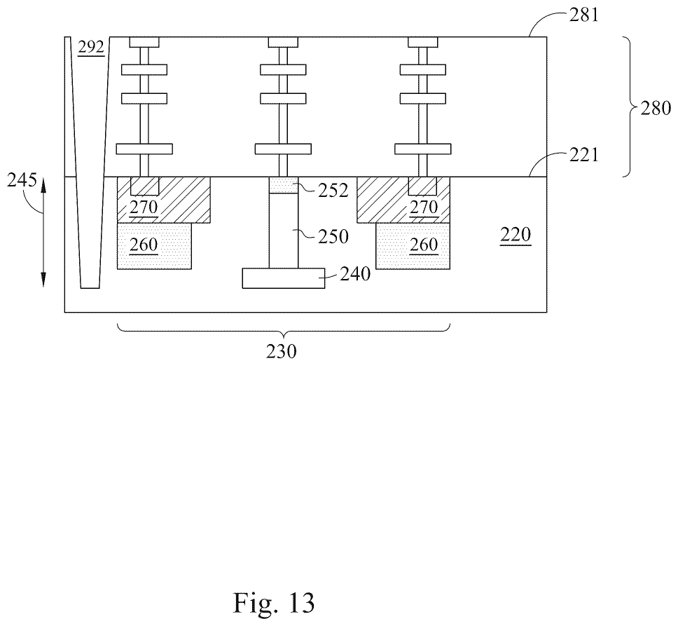

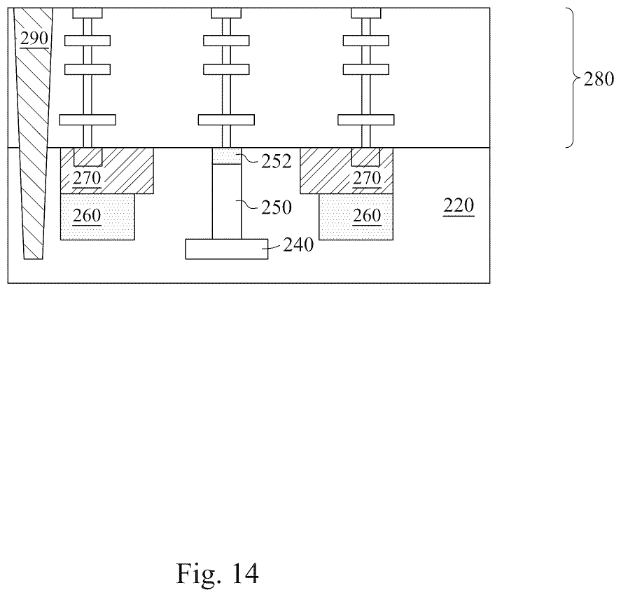

In optional step 366 of FIG. 3B and as illustrated in FIG. 13, a trench 292 is formed. This is usually performed by patterning and etching. In this embodiment, the trench 292 extends from the first side 281 of the interconnect layer into the substrate at least to the first depth 245 where the first deep well of the first dopant type 240 is located. The trench 292 is formed off to at least one side of the image sensor 230, and in some embodiments can surround the entire image sensor. In optional step 368 of FIG. 3B and as illustrated in FIG. 14, the trench is filled with an opaque material to form the opaque wall 290. Again, the opaque material may be a metal such as aluminum or copper, or could be an opaque dielectric material. If the opaque wall 290 is desired to be formed only in the substrate 220 as in the embodiment of FIG. 1C, steps 366, 368 are performed prior to step 364 where the interconnect layer 280 is formed.

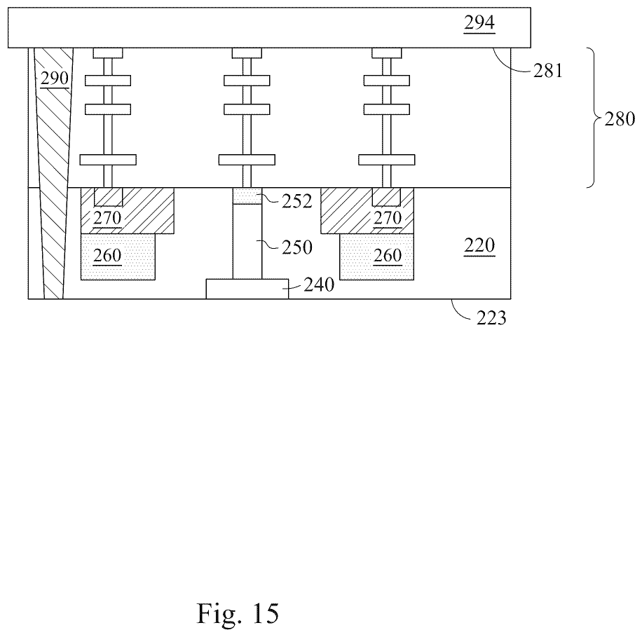

Continuing, in step 370 of FIG. 3B and as illustrated in FIG. 15, a carrier wafer 294 is applied to the first side 281 of the interconnect layer 280. Then, in step 372, the second side 223 of the substrate 220 is grinded down to remove excess material until the first deep well of the first dopant type 240 is exposed.

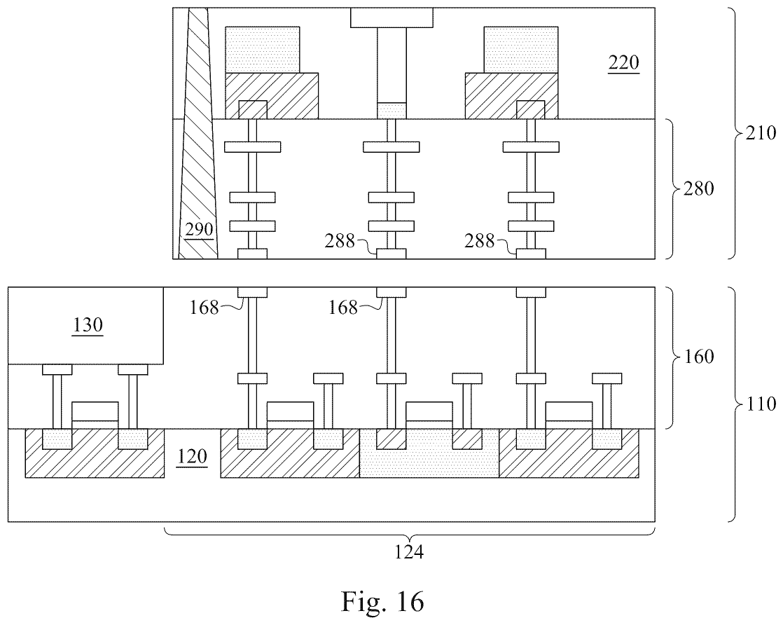

FIG. 16 shows the top die 210 after it is flipped over and the carrier wafer 294 is removed. Then, in step 374 of FIG. 3B, the top die 210 is bonded to the bottom die 110. More specifically, the top die is bonded over the logic area 124 of the bottom die. The top die is aligned so that the opaque wall 290 of the top die is placed between the LED 130 and the image sensor 230. As seen here, the bond pads 288 of the top die are aligned with the bond pads 168 of the bottom die. Fusion bonding, such as hybrid bonding, may be used to bond the two dies together and obtain the ToF sensor.

In this regard, hybrid bonding refers to the use of both a dielectric bond and a metal bond to form an interconnection between the two dies. Each die includes a dielectric layer which contains a plurality of metal bond pads. The dielectric layer on each package is activated (usually by plasma) to be hydrophilic. When the metal bond pads of the two dies are aligned and the dielectric layers of the two dies are brought together, the dielectric layers bond together, referred to herein as a hybrid bond layer. The two-die system is then annealed to cause the metal bond pads to bond together and expand and fill any gaps. The resulting sensor 101 is shown in FIG. 1A.

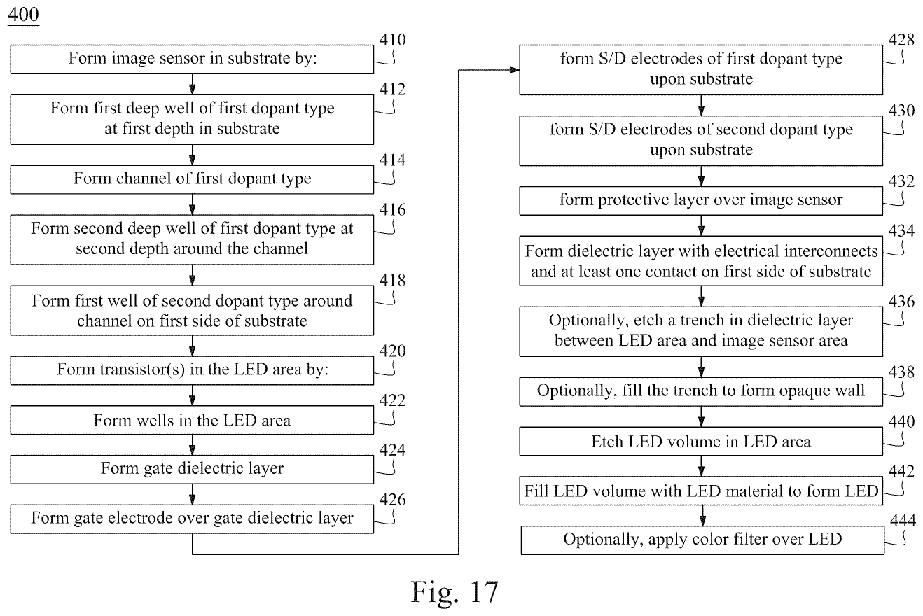

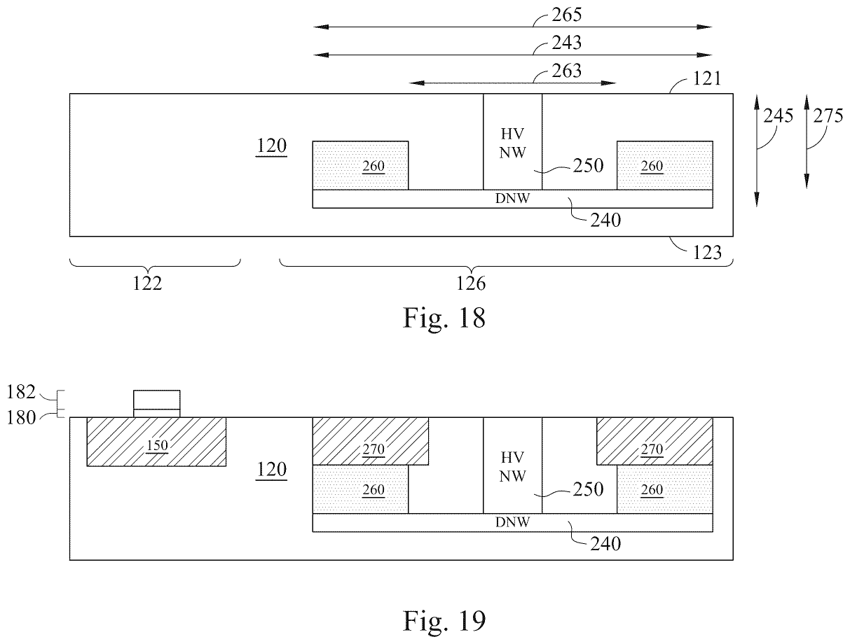

FIG. 17 is a flow chart illustrating a method 400 for making a Time-of-Flight (ToF) sensor, more particularly an FSI ToF sensor. Some steps of the method are also illustrated in FIGS. 18-25. Again, the method steps are discussed below in terms of forming a single sensor, but should also be broadly construed as applying to the concurrent formation of multiple sensor components. Additional steps may be performed between the various steps described herein, and some are omitted merely for clarity. Not all method steps may be needed to obtain the structures disclosed herein. Additionally, some of the method steps can be performed simultaneously, or in a different order than as shown or described here.

Referring first to FIG. 18, the substrate 120 has a first side 121 and an opposite second side 123. The substrate 120 also includes an LED area 122 and an image sensor area 126.

Next, as indicated in step 410 of FIG. 17, an image sensor (SPAD) is formed in the image sensor area of the substrate. The image sensor may be formed in multiple steps, similar to those described for the top die 210 in FIG. 3B.

In step 412 of FIG. 17 and as illustrated in FIG. 18, a first deep well of a first dopant type 240 is formed in the substrate at a first depth 245. The first deep well of the first dopant type may be considered as being proximate the second side 123 of the substrate. Then, in step 414, a channel of the first dopant type 250 is formed in the substrate. The channel contacts the first deep well of the first dopant type 240 at one end, and extends to the first side 121 of the substrate. Put another way, the channel is exposed on the first side 121 of the substrate. In step 416, the second deep well of the first dopant type 260 is formed around the first deep well of the first dopant type 240 at a second depth 275 which is different from the first depth 245. The second deep well of the first dopant type 260 can also be described as being formed around the channel 250. It is noted that steps 414 and 416 can be performed in any order. These steps may be performed by ion implantation. Again, the channel may be formed in multiple implantation steps if desired.

As illustrated here, the second well of the first dopant type 260 has an inner width 263 and an outer width 265. The first deep well of the first dopant type 240 may have a width 243 that is greater than the inner width 263, and in this embodiment the width 243 is about equal to the outer width 265.

Then, in step 418 of FIG. 17 and as illustrated in FIG. 19, the first well of the second dopant type 270 is formed upon the first side 121 of the substrate. Again, the first well of the second dopant type 270 is exposed upon the first side 121 of the substrate, and also contacts the second deep well of the first dopant type 260. This may be done using ion implantation.

Continuing, in step 420 of FIG. 17, one or more transistors are formed in the LED area in multiple steps. In step 422, one or more wells 150 are formed in the LED area. If they are of the first dopant type, they could potentially be formed concurrently with part of the channel 250. If they are of the second dopant type, they may be formed concurrently with the first well of the second dopant type 270. Alternatively, the well(s) 150 can be formed in their own separate ion implantation step.

In step 424 of FIG. 17, a dielectric layer is formed upon the substrate and patterned to form the gate dielectric layer 180 of each transistor. In step 426, a gate material is deposited and patterned to form the gate electrode 182 of each transistor. The gate electrode 182 is located upon the gate dielectric layer 180. The resulting structure is shown in FIG. 19.

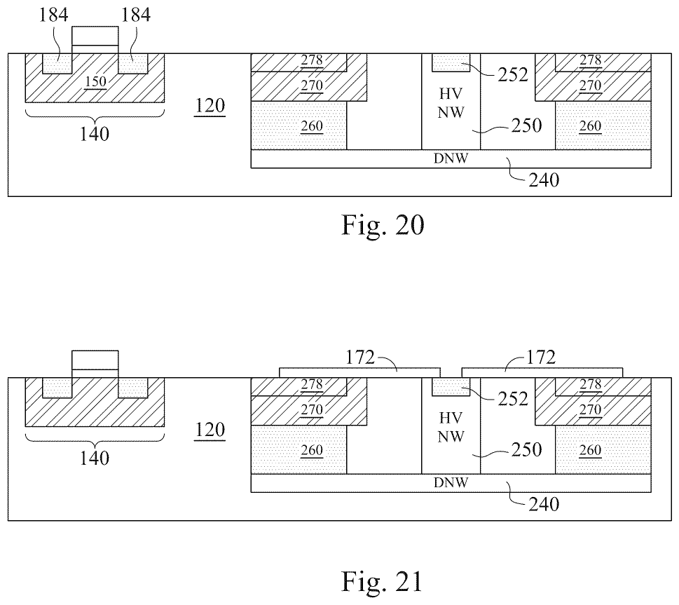

In step 428 of FIG. 17 and as illustrated in FIG. 20, one or more source/drain (S/D) electrodes of the first dopant type are formed upon the substrate. In the image sensor area, one S/D electrode of the first dopant type 252 contacts the channel 250, or could alternatively be described as being formed within the channel. This electrode can also be referred to as a central S/D electrode of the image sensor, although in some embodiments is not required. As illustrated here, two S/D electrodes of the first dopant type 184 are also formed within the well 150 in the LED area to form transistor 140.

In step 430 of FIG. 17, one or more source/drain (S/D) electrodes of the second dopant type are formed upon the substrate. As illustrated here, two S/D electrodes of the second dopant type 278 are also formed within the first well of the second dopant type 270 in the image sensor. These electrodes can also be referred to as peripheral S/D electrodes of the image sensor. The resulting structure is shown in FIG. 20.

In step 432 of FIG. 17 and as illustrated in FIG. 21, a protective layer 172 is formed upon the substrate 120 and over the image sensor 230. The protective layer is shaped so that, as best seen in FIG. 2B, the central S/D electrode 252 and the peripheral S/D electrodes 278 are exposed when seen from a plan view. In particular embodiments, the protective layer is a resist protective oxide (RPO) layer. The RPO layer may be a dielectric material, such as silicon dioxide, silicon oxynitride, or other suitable material.

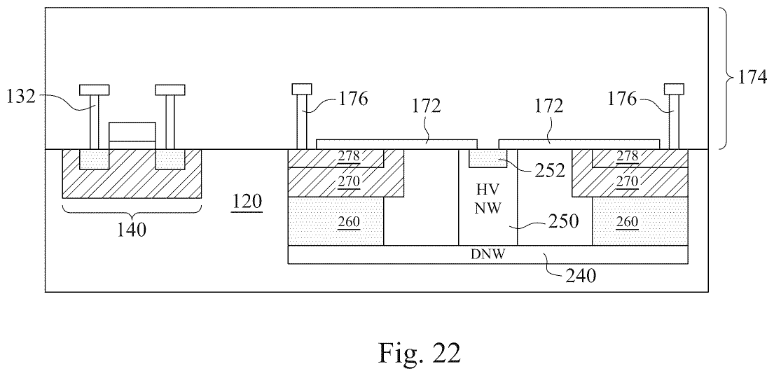

Next, in step 434 of FIG. 17 and as illustrated in FIG. 22, a dielectric layer 174 is formed upon the first side 121 of the substrate. Electrical interconnects 132 are also formed within the dielectric layer, for example in the LED area. At least one contact 176 extends from a peripheral S/D electrode 278 into the dielectric layer. Here, two such contacts are illustrated. The dielectric layer 174 and the at least one contact 176 may be formed by repeated steps of deposition and etching (of dielectric material and electrically conductive material) to obtain the desired structure.

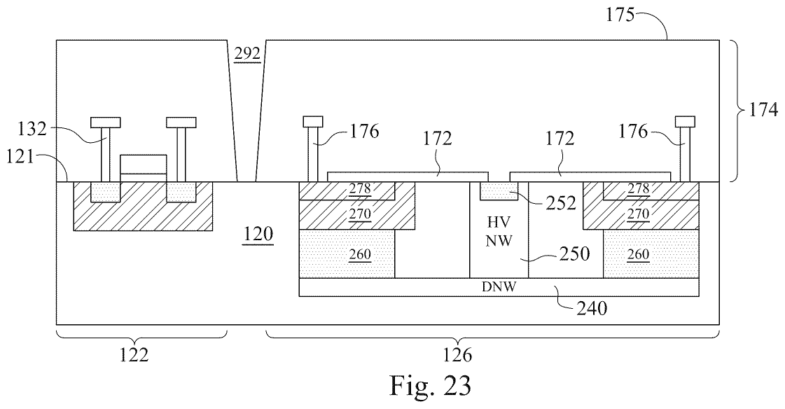

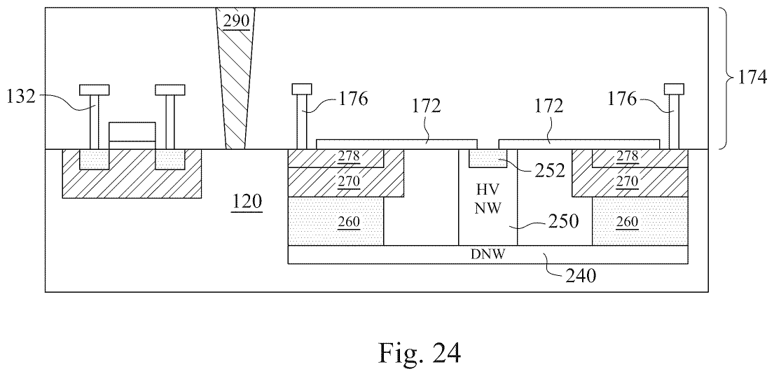

Continuing, in optional step 436 of FIG. 17 and as illustrated in FIG. 23, a trench 292 is formed in the dielectric layer 174. The trench 292 extends from the top surface 175 of the dielectric layer to the first side 121 of the substrate. The trench 292 is formed between the LED area 122 and the image sensor area 126, and in some embodiments can surround the entire image sensor. In optional step 438 of FIG. 17 and as illustrated in FIG. 24, the trench is filled with an opaque material to form the opaque wall 290.

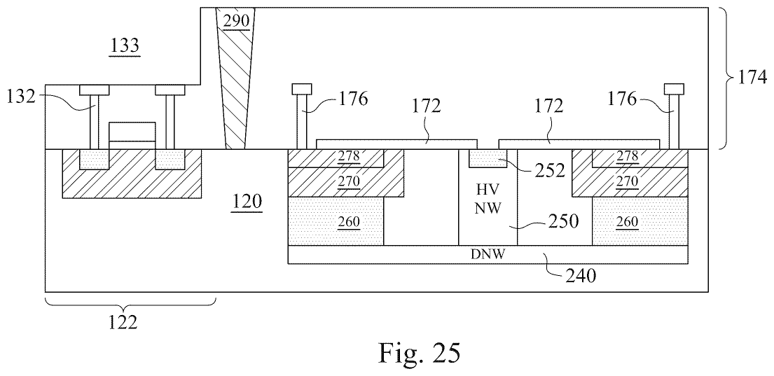

Next, as indicated in step 440 of FIG. 17 and as illustrated in FIG. 25, the dielectric layer 174 is etched in the LED area 122 to form an LED volume 133. Then, as indicated in step 442 of FIG. 17, the LED volume is filled with an LED material to form the LED 130. The resulting structure corresponds to the sensor 104 of FIG. 2A. In optional step 444, a color filter may be applied if desired.

The structures and methods of the present disclosure discussed above refer to dielectric layers. Such dielectric layers can generally be made from any suitable dielectric material or combination thereof, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (HfSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). The dielectric layer may be formed by any suitable means, including chemical vapor deposition (CVD), physical vapor deposition (PVD), atomic layer deposition (ALD), thermal oxidation, or other suitable methods.

It is also noted that certain conventional steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. The photoresist composition is baked or cured to remove the solvent and harden the photoresist layer. The photoresist layer is then patterned via exposure to radiation. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer. The photoresist layer is then developed using a developer. The soluble portions of the photoresist layer are dissolved and washed away during the development step, leaving behind a photoresist pattern (i.e. a mask).

Continuing, portions of the given layer below the patterned photoresist mask are now exposed. Etching transfers the photoresist pattern to the given layer below the patterned photoresist mask. After use, the mask can be removed, for example, using various solvents or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

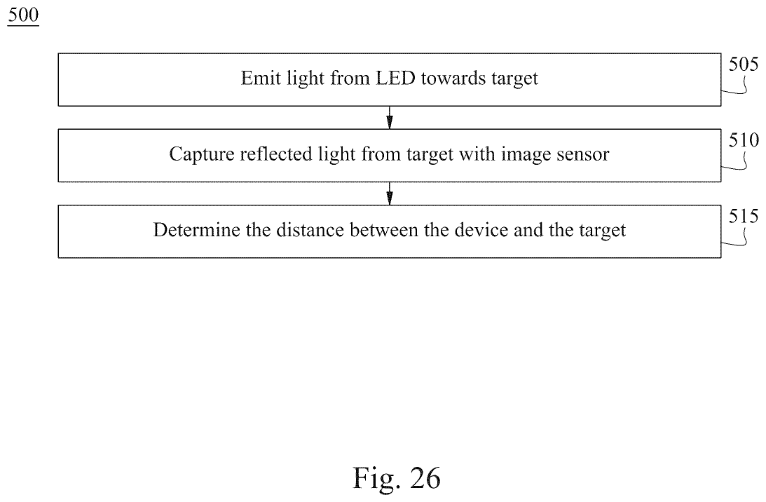

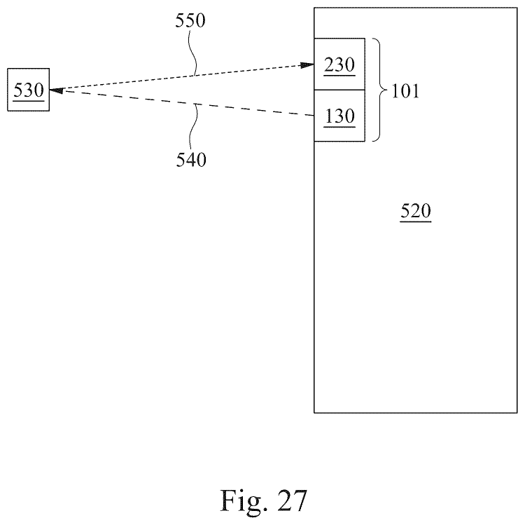

FIG. 26 is a flow chart illustrating a method 500 for using a Time-of-Flight (ToF) sensor to measure distance. The method will also be discussed with reference to FIG. 27.

Referring initially to FIG. 27, the sensor 101 is illustrated within a suitable device 520, such as a cellphone, a watch, a pair of glasses, a vehicle such as an automobile, etc. The sensor includes an image sensor 230 and a light source such as the LED 130. A target 530 is also included in the schematic diagram, and it is desired to measure the distance between the device 520 and the target 530. It is noted that this distance measurement may be used, for example, to provide feedback and control the distance between the device and the target, or to change the focus of a camera lens.

In step 505 of FIG. 27, light is emitted by the LED towards the target. This light path is illustrated by arrow 540. In step 510, light reflected by the target travels back towards, and is captured by, the image sensor 230. This light path is illustrated by arrow 550. In step 515, the distance is determined. This may be done in the logic area or in another area of the device.

There exist at least two techniques to measure the time-of-flight. In the direct method, a START signal is synchronized with the light source, and a STOP signal is generated by the detector when the reflected light is detected. The time difference between the START and STOP signals is evaluated to determine the distance. In the indirect method, a continuous sinusoidal light wave is emitted and the phase difference between outgoing and incoming signals is measured, which is used to determine the time difference using a predefined algorithm.

The sensors of the present disclosure have several advantages. Initially, better process control and quality control can be obtained compared to conventional structures without additional process steps or additional masks. The entire sensor can also be produced at a single location. This reduces costs and improves yield. Product cycle time is also reduced. The volume of the sensor is reduced. It is believed that the area of the sensor can be reduced by more than 50%, and the height/thickness of the sensor can be reduced by more than 70% compared to conventional sensors. Any housing in which the sensors are placed can be much smaller than conventional housings. The sensors also have reduced power consumption. They can thus be used in small devices such as watches, cellphones, or eyeglasses or other small mobile systems, as well as larger devices where distance measurement might be useful, such as vehicles like automobiles.

Some embodiments of the present disclosure thus relate to methods for making a Time-of-Flight (ToF) sensor. A light-emitting diode (LED) and a logic area are formed upon a semiconducting substrate of a bottom die. An image sensor is formed in a substrate of a top die. The top die is bonded over the logic area of the bottom die. When an opaque wall is present, the opaque wall is placed between the light-emitting diode and the image sensor, to obtain the ToF sensor.

Other embodiments disclosed herein relate to a Time-of-Flight (ToF) sensor that comprises a bottom die and a top die. The bottom die includes a light-emitting diode (LED) and a logic area upon a semiconducting substrate. The top die includes an image sensor in a substrate. The top die is located over and electrically connected to the logic area of the bottom die. When an opaque wall is present, the opaque wall is located between the light-emitting diode and the image sensor.

Also described in various embodiments herein are top dies that can be used in making a ToF sensor. The top die includes an image sensor and an opaque wall in a substrate.

Also described in various embodiments herein are methods of forming such a top die. A first deep well of a first dopant type is formed at a first depth in the substrate. A channel of the first dopant type is formed that contacts the first deep well. A second deep well of the first dopant type is formed around the channel at a second depth in the substrate. A first well of a second dopant type is formed upon a first side of the substrate around the channel and contacting the second deep well of the first dopant type. A source/drain electrode of the first dopant type is formed that contacts the channel. A source/drain electrode of the second dopant type is formed within the first well of the second dopant type. An interconnect layer is formed upon the first side of the substrate, the interconnect layer including metal routing and contact vias. The opaque wall is formed in at least the substrate (and perhaps through the interconnect layer as well) on at least one side outside of the first well of the second dopant type. This is done by etching a trench, and then filling the trench with an opaque material.

The present disclosure also relates in various embodiments to bottom dies that can be used in making a ToF sensor. The bottom die includes a light-emitting diode (LED) and a logic area upon a semiconducting substrate. The logic area includes active devices, such as transistors. An interconnect layer is formed upon the first side of the substrate, the interconnect layer including metal routing and contact vias. In particular embodiments, an opaque wall is present extending through the interconnect layer, and potentially into the substrate as well. The opaque wall is located between the light-emitting diode and the logic area.

The present disclosure also relates in various embodiments to methods of forming such a bottom die. Active devices are formed in the logic area and in an LED area of the semiconducting substrate. An interconnect layer is then formed upon the substrate, the interconnect layer including metal routing and contact vias. The interconnect layer is etched in the LED area to form an LED volume. The LED volume is then filled with an LED material to form the LED. The opaque wall is formed by etching a trench, and then filling the trench with an opaque material.

The present disclosure also relates in various embodiments to other Time-of-Flight (ToF) sensors, such as Front-Side-Illuminated (FSI) sensors. The ToF sensors include an image sensor in a semiconducting substrate. An light-emitting diode (LED) is present upon the substrate adjacent the image sensor. A protective layer is located upon the substrate over the image sensor that exposes a central source/drain electrode and a peripheral source/drain electrode of the image sensor. A dielectric layer is present upon the substrate. At least one contact extends from the peripheral source/drain electrode of the image sensor into the dielectric layer. An opaque wall may be present in the dielectric layer, and when present may be located between the light-emitting diode and the image sensor.

Also described in various embodiments herein are methods of making such a ToF sensor. In an image sensor area, a first deep well of a first dopant type is formed at a first depth in the semiconducting substrate. A channel of the first dopant type is formed that contacts the first deep well. A second deep well of the first dopant type is formed around the channel at a second depth in the substrate. A first well of a second dopant type is formed upon a first side of the substrate around the channel and contacting the second deep well of the first dopant type. Active devices, such as transistors, are then formed in an LED area. In the image sensor area, a source/drain electrode of the first dopant type is formed that contacts the channel. A source/drain electrode of the second dopant type is formed within the first well of the second dopant type. Source/drain electrodes are concurrently formed for the transistors in the LED area. A protective layer is formed over the image sensor. A dielectric layer is formed upon the first side of the substrate, the interconnect layer including electrical interconnects and at least one contact extending from a peripheral source/drain electrode. An opaque wall can be formed in at least the dielectric layer (and perhaps through the interconnect layer as well) between the LED area and the image sensor area. The opaque wall may be formed by etching a trench, and then filling the trench with an opaque material. The dielectric layer is etched in the LED area to form an LED volume. The LED volume is then filled with an LED material to form the LED.

Other embodiments disclosed herein relate to devices that include ToF sensors as described herein. The devices may be a cellphone, a watch, a pair of glasses, an automobile, a motorized or battery-powered vehicle, etc.

Some further embodiments of the present disclosure also relate to methods of using such ToF sensors to measure the distance between a device and a target. Light is emitted by the LED towards the target. Light reflected by the target is captured by the image sensor. The distance is then determined using timing information.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for making a Time-of-Flight (ToF) sensor, comprising:
forming a light-emitting diode (LED) and a logic area upon a semiconducting substrate of a bottom die;
forming an image sensor in a substrate of a top die; and
bonding the top die over the logic area of the bottom die to obtain the ToF sensor.

2. The method of claim 1, further comprising:
forming an opaque wall in at least the substrate of the top die;
wherein the opaque wall is placed between the light-emitting diode and the image sensor during the bonding of the top die over the logic area.

3. The method of claim 1, wherein the top die is formed by:
forming a first deep well of a first dopant type at a first depth in the substrate;
forming a channel of the first dopant type contacting the first deep well;
forming a second deep well of the first dopant type around the channel at a second depth in the substrate;
forming a first well of a second dopant type upon a first side of the substrate around the channel and contacting the second deep well of the first dopant type;
forming a source/drain electrode of the first dopant type contacting the channel;
forming a source/drain electrode of the second dopant type within the first well of the second dopant type; and
forming an interconnect layer upon the first side of the substrate, the interconnect layer including metal routing and contact vias.

4. The method of claim 3, further comprising forming an opaque wall in at least the substrate on at least one side outside of the first well of the second dopant type.

5. The method of claim 4, wherein the opaque wall also extends through the interconnect layer of the top die.

6. The method of claim 3, wherein the first dopant type is an n-type dopant, and the second dopant type is a p-type dopant; or
wherein the first dopant type is a p-type dopant, and the second dopant type is an n-type dopant.

7. The method of claim 3, wherein the source/drain electrode of the first dopant type of the top die is electrically connected to an active device in the logic area on the bottom die located within a well of the first dopant type; or
wherein the source/drain electrode of the second dopant type of the top die is electrically connected to an active device in the logic area on the bottom die located within a well of the second dopant type.

8. The method of claim 3, further comprising grinding a second side of the substrate to expose the first deep well of the first dopant type.

9. The method of claim 1, wherein the bottom die is formed by:
forming active devices in the logic area and in an LED area of the semiconducting substrate;
forming an interconnect layer upon the semiconducting substrate, the interconnect layer including metal routing and contact vias;
etching the interconnect layer in the LED area to form an LED volume; and
filling the LED volume with an LED material to form the LED.

10. A Time-of-Flight (ToF) sensor, comprising:
a bottom die including a light-emitting diode (LED) and a logic area upon a semiconducting substrate; and
a top die including an image sensor; and
wherein the top die is located over and electrically connected to the logic area of the bottom die, and wherein an opaque wall is located between the light-emitting diode and the image sensor.

11. The ToF sensor of claim 10, wherein the top die further comprises the opaque wall in a substrate.

12. The ToF sensor of claim 11, wherein the opaque wall is made of a metal.

13. The ToF sensor of claim 11, wherein the bottom die further comprises an interconnect layer upon the semiconducting substrate, and an opaque wall extending through the interconnect layer between the LED and the logic area; and wherein the opaque wall of the bottom die is aligned with the opaque wall of the top die.

14. The ToF sensor of claim 10, wherein the image sensor comprises an avalanche photodiode.

15. The ToF sensor of claim 10, further comprising a color filter upon the LED.

16. A Time-of-Flight (ToF) sensor, comprising:
an image sensor in a semiconducting substrate;
a light-emitting diode (LED) upon the semiconducting substrate adjacent the image sensor;
a protective layer upon the semiconducting substrate over the image sensor that exposes a central source/drain electrode and a peripheral source/drain electrode of the image sensor;
a dielectric layer upon the semiconducting substrate; and
at least one contact extending from the peripheral source/drain electrode of the image sensor into the dielectric layer.

17. The ToF sensor of claim 16, further comprising an opaque wall in the dielectric layer located between the light-emitting diode and the image sensor.

18. The ToF sensor of claim 16, wherein the protective layer is a resist protective oxide.

19. The ToF sensor of claim 16, wherein the image sensor comprises an avalanche photodiode, such as a single photon avalanche photodiode.

20. The ToF sensor of claim 16, wherein the image sensor comprises:
a first deep well of a first dopant type at a first depth in the semiconducting substrate;
a channel of the first dopant type contacting the first deep well and extending towards a front side of the semiconducting substrate;
a second deep well of the first dopant type around the first deep well at a second depth in the semiconducting substrate;
a first well of a second dopant type adjacent the front side of the semiconducting substrate around the first deep well and contacting the second deep well of the first dopant type;
a source/drain electrode of the first dopant type contacting the channel; and
a source/drain electrode of the second dopant type within the first well of the second dopant type.
